(19) United States
(12) Patent Application Publication
(10) Pub. No.: US 2026/0305247 A1
(43) Pub. Date: Oct. 1, 2026

(54) MARK DETECTION METHOD, MARK DETECTION APPARATUS, PATTERN FORMATION APPARATUS, AND ARTICLE MANUFACTURING METHOD

(71) Applicant: CANON KABUSHIKI KAISHA, Tokyo (JP)

(72) Inventors: TOMOKAZU TAKI, Tochigi (JP); MIZUKI ISHIMOTO, Tochigi (JP)

(21) Appl. No.: 19/572,704

(22) Filed: Mar. 19, 2026

(30) Foreign Application Priority Data
Mar. 27, 2025 (JP) 2025-054122

(51) Int. Cl. H10P 72/50; G01B 11/27; G03F 7/00; G03F 9/00

(52) U.S. Cl. CPC H10P 72/53; G01B 11/272; G03F 7/0002; G03F 9/7019; G03F 9/7042; G03F 9/7069; G03F 9/7088

(57) ABSTRACT

A mark detection method includes adjusting, as an adjustment process, an illumination condition for mark detection by using the substrate mark and the mold mark, supplying, as a supply process, the imprint material onto the substrate after the adjustment process, measuring, as a measurement process, a relative position between the substrate mark and the mold mark by detecting the substrate mark and the mold mark based on the illumination condition after the supply process, and aligning the substrate and the mold based on the relative position. The substrate mark and the mold mark used in the adjustment process are identical to the substrate mark and the mold mark detected in the measurement process.

### BACKGROUND

### Field of the Technology

The present disclosure relates to a mark detection method for detecting marks formed on a mold and a substrate, a mark detection apparatus, a pattern formation apparatus, and an article manufacturing method.

### Description of the Related Art

As a method of manufacturing articles such as semiconductor devices and optical members, an imprint technology is known in which a pattern is formed on a curable composition (imprint material) on a substrate by using a mold. In the imprint technology, an imprint material is supplied onto a substrate, and a mold is brought into contact (mold pressing) with the supplied imprint material. Then, a pattern of the imprint material is formed on the substrate by separating (releasing) the mold from the cured imprint material, after the imprint material is cured in a state where the imprint material and the mold are in contact with each other.

To form a pattern accurately on a desired position of the substrate, the relative position between a pattern forming area of the mold and a to-be-patterned area on the substrate needs to be aligned at a timing before the imprint material is cured. As an alignment method, a method of using mark detection is known. The alignment method is a method of relatively aligning the pattern forming area and the to-be-patterned area by detecting marks (alignment marks) used for alignment and formed on the mold and the substrate, and measuring the relative positions of the marks.

To perform the mark detection accurately, an illumination condition for the mark detection needs to be appropriately set. Japanese Patent Laid-open No. 2017-183364 describes a method of reducing the adjustment time of the illumination conditions for a second substrate by adjusting illumination conditions using alignment marks on a first substrate, and detecting alignment marks on the second substrate by using the illumination conditions adjusted for the first substrate. Japanese Patent Laid-open No. 2018-152374 describes a method of adjusting a wavelength range and intensity (illumination condition) of light combined using a plurality of light sources and optical elements, by using one neutral density (ND) filter selected from a plurality of ND filters different in transmittance.

However, in Japanese Patent Laid-open No. 2017-183364, the illumination conditions adjusted for the first substrate are used for the second substrate, but in a case where the reflectance ratios of the alignment marks of the first substrate and the second substrate are different from each other, an illumination condition adjusted for the first substrate may not necessarily be the most appropriate illumination condition for the second substrate.

### SUMMARY

The present disclosure is directed to a mark detection method capable of performing mark detection under an appropriate illumination condition for each substrate, and reducing a time difference from when an imprint material is supplied onto a substrate until when mold pressing is performed.

According to an aspect of the present disclosure, a mark detection method for detecting a substrate mark formed on a substrate and a mold mark formed on a mold when a pattern is formed using the mold on an imprint material supplied on the substrate includes adjusting, as an adjustment process, an illumination condition for mark detection by using the substrate mark and the mold mark, supplying, as a supply process, the imprint material onto the substrate after the adjustment process, measuring, as a first measurement process, a first relative position between the substrate mark and the mold mark by detecting the substrate mark and the mold mark based on the illumination condition after the supply process, and aligning, as an alignment process, the substrate and the mold based on the first relative position. The substrate mark and the mold mark used in the adjustment process are identical to the substrate mark and the mold mark detected in the first measurement process.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating an imprint apparatus according to a first embodiment.

FIG. 2 is a flowchart illustrating imprint processing according to the first embodiment.

FIGS. 3A, 3B, 3C, and 3D are diagrams illustrating a pattern formation method according to the first embodiment.

FIG. 4 is a flowchart illustrating imprint processing according to a second embodiment.

FIG. 5 is a diagram illustrating an imprint apparatus according to another embodiment.

### DESCRIPTION OF THE EMBODIMENTS

In a case where an illumination condition adjusted for a first substrate is used for a second substrate, when a reflectance ratio of an alignment mark on the first substrate is different from that of the second substrate, the illumination condition adjusted for the first substrate may not necessarily be a most appropriate illumination condition for the second substrate.

Thus, the mark detection method in the following embodiments is directed to a mark detection method capable of performing mark detection under an appropriate illumination condition for each substrate, and reducing a time difference from when an imprint material is supplied onto the substrate until when mold pressing is performed.

Hereinbelow, the embodiments of the present disclosure will be described in detail with reference to the attached drawings. In addition, in the drawings, the same reference numbers are assigned to the same components, and duplicate descriptions thereof will be omitted.

### FIRST EMBODIMENT

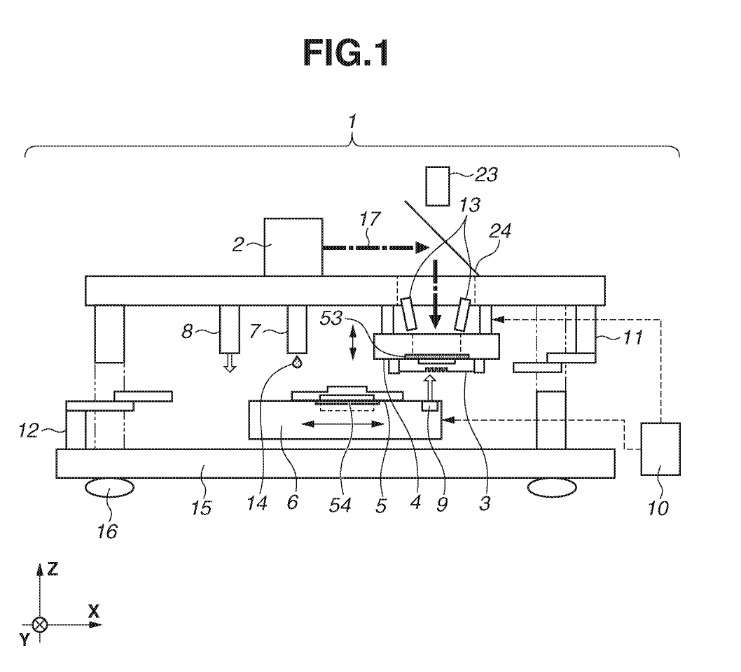

FIG. 1 is a schematic diagram illustrating a configuration of an imprint apparatus 1 according to a first embodiment. The configuration of the imprint apparatus 1 will be described with reference to FIG. 1. In FIG. 1, axes are determined in such a manner that a surface on which a substrate 5 is placed is an XY plane, and a direction orthogonal thereto is a Z direction (height direction of the imprint apparatus 1) as illustrated in FIG. 1. The imprint apparatus 1 is an apparatus for forming a pattern of a cured material onto which a concave and convex pattern of a mold is transferred, by bringing a mold into contact with an imprint material supplied on a substrate, and applying energy for curing the imprint material thereto. The imprint apparatus 1 in FIG. 1 is used for manufacturing devices (e.g., semiconductor devices) serving as articles. In the present embodiment, the imprint apparatus 1 employing a light curing method will be described.

Further, the imprint apparatus 1 according to the first embodiment is an imprint apparatus for manufacturing a replica mold used in replica mold manufacturing processes. The imprint apparatus 1 is an apparatus for forming (transferring) a pattern using a master mold 3 on a blank mold (i.e., the replica mold before the pattern is formed) serving as a substrate 5.

### Imprint Apparatus

The imprint apparatus 1 includes an illumination system unit 2, a mold holding portion (hereinbelow, also referred to as an imprint head) 4 for holding the master mold 3, a substrate holding portion (hereinbelow, also referred to as a stage) 6 for holding the substrate 5, a supply portion (hereinbelow, also referred to as a dispenser) 7 for supplying an imprint material 14, and a mold conveyance apparatus 11 for conveying the master mold 3. Further, the imprint apparatus 1 includes a substrate conveyance apparatus 12 for conveying the substrate 5, and a control unit 10 for controlling operations of the imprint apparatus 1.

The illumination system unit 2 is an illumination unit for emitting light (ultraviolet rays) 17 for curing the imprint material 14 to the master mold 3 when imprint processing is performed. The illumination system unit 2 includes a light source and an optical member for adjusting light emitted from the light source to be suitable for irradiating the imprint material 14.

The master mold 3 is a mold with a predetermined pattern formed on its surface opposing the substrate 5 in a state held by the mold holding portion 4. The mold holding portion 4 includes a mold chuck 53 for holding the master mold 3 by vacuum suction or electrostatic adsorption. The mold holding portion 4 has a drive mechanism for holding and moving the master mold 3 in the Z direction. Further, the mold holding portion 4 may have a drive mechanism for inclining the master mold 3 according to the height and inclination of the master mold 3 or the substrate 5, or a drive mechanism for moving the master mold 3 in the XY plane.

Above the master mold 3 in the mold holding portion 4, through-the-mask (TTM) scopes 13 are provided. Each of the TTM scopes 13 is a mark detection unit including an illumination system and an image capturing system for detecting a mark (mold mark) provided on the master mold 3 and a mark (substrate mark) provided on the substrate 5. The illumination system of each of the TTM scopes 13 is provided with a light source for emitting light for irradiating the marks, and an adjustment unit for adjusting the illumination condition of the light emitted from the light source.

The adjustment unit includes a wavelength filter for selecting wavelengths of the light emitted from the light source, and a neutral density (ND) filter for adjusting the intensity of the light from the light source. The image capturing system of each of the TTM scopes 13 includes a light receiving element such as an image sensor.

In general, the TTM scopes 13 are arranged each at a corner of the four corners of the pattern forming area. By arranging the plurality of TTM scopes 13, it is possible to measure a plurality of marks at a time. In a case where the plurality of TTM scopes 13 is arranged, the TTM scopes 13 can be driven independently in XY directions. From the mark detection result by the TTM scopes 13, it is possible to measure the misalignment between the master mold 3 and the substrate 5 (relative position between the master mold 3 and substrate 5) in the XY direction and XY rotation direction. The alignment between the master mold 3 and the substrate 5 is performed using the measurement result.

The stage (i.e., substrate holding portion) 6 includes a substrate chuck 54 for holding the substrate 5 by vacuum suction or electrostatic adsorption. The stage 6 is a holding unit including a drive mechanism for moving the substrate 5 held by the stage 6 in the XY plane. It is desirable for the stage 6 to have a drive mechanism for rotationally driving the substrate 5 around the Z axis. The stage 6 moves along a stage base plate 15 of the imprint apparatus 1. In this case, the reference for the stage 6 in the Z direction and the inclination when the stage 6 is moved in the XY plane is the stage base plate 15. The stage base plate 15 is configured on the mount 16, and thus the imprint apparatus 1 is less susceptible to vibrations from the floor. Further, the stage 6 may have a drive mechanism for moving the substrate 5 in the Z direction and a rotation mechanism for rotating the substrate 5 around the X and Y axes.

The stage 6 is provided with a mold measurement sensor 9 that can measure a surface of the master mold 3. The mold measurement sensor 9 is a distance measurement device that can measure the distance (shape) to the surface of the master mold 3 in the Z axis direction. Based on the measurement result of the mold measurement sensor 9, the height of the surface of the master mold 3 can be obtained. The mold measurement sensor 9 can measure each position on the whole surface of the master mold 3 by the stage 6 moving along the XY plane. The mold measurement sensor 9 does not necessarily need to be provided on the stage 6 and may also be provided on a mechanism different from the stage 6. In this case, the surface shape (distances) of the master mold 3 can also be measured by the mold measurement sensor 9 moving along the XY plane.

Further, the imprint apparatus 1 is provided with a substrate measurement sensor 8 that can measure a surface of the substrate 5. The substrate measurement sensor 8 is a distance measurement device that can measure a distance (shape) to the surface of the substrate 5 in the Z axis direction. Based on the measurement result of the substrate measurement sensor 8, the height of the surface of the substrate 5 can be obtained. The substrate measurement sensor 8 can measure each position on the whole surface of the substrate 5 by the stage 6 moving along the XY plane. The substrate measurement sensor 8 may measure the surface of the substrate 5 by moving along the XY plane. An optical sensor such as an interferometer is used as the height measurement sensor such as the substrate measurement sensor 8 and the mold measurement sensor 9.

The supply portion (dispenser) 7 is a supply unit for supplying the imprint material 14 onto the substrate 5. As the imprint material 14, a curable composition (also referred to as uncured state resin) that is cured by receiving curing energy is used. As the curing energy, electromagnetic waves, heat, or the like are used. For example, as the electromagnetic waves, light with its wavelength selected from a range of 10 nm or more and 1 mm or less, such as infrared light, visible light, and ultraviolet light, is used.

The curable composition is a composition that is cured by the irradiation with light or by heating. From among these kinds of curable compositions, the light curable composition cured by light contains at least a polymerizable compound and a photopolymerization initiator, and may also contain a non-polymerizable compound or a solvent as needed. The non-polymerizable compound is at least a kind of compound selected from a group containing a sensitizer, a hydrogen donor, an internal release agent, a surfactant, an antioxidant, a polymer component, and the like.

The imprint material 14 is applied onto the substrate 5 in a film manner by a spin coater or a slit coater. Alternatively, the imprint material 14 may be applied onto the substrate 5 in a droplet state by a liquid injection head, or an island-like or a film-like state formed by a plurality of liquid droplets connecting together. The viscosity (viscosity at 25° C) of the imprint material 14 is, for example, 1 mPa∙s or more and 100 mPa∙s or less.

As the material of the substrate 5, glass, ceramic, metal, semiconductor, resin, or the like is used, and a member made of another material different from the substrate 5 may also be formed on the surface of the substrate 5, as needed. Specifically, the substrate 5 is a silicon wafer, a compound semiconductor wafer, or a quartz glass plate.

The mold conveyance apparatus 11 is a conveyance unit configured to carry the master mold 3 onto the mold holding portion 4 or carry the master mold 3 out of the imprint apparatus 1. Further, the substrate conveyance apparatus 12 is a conveyance unit configured to carry the substrate 5 (replica mold) onto the stage 6 or carry the substrate 5 out of the imprint apparatus 1.

The control unit 10 controls operations of component units of the imprint apparatus 1 and acquires various kinds of sensor values. The control unit 10 is composed of a computer or a sequencer (not illustrated) connected to the component units of the imprint apparatus 1, and the control unit 10 includes a processing unit and memories. The control unit 10 may be provided in the imprint apparatus 1 or may be provided at a place different from the imprint apparatus 1 to be remotely controlled.

Above the master mold 3, a shot whole area observation scope 23 may be arranged.

The shot whole area observation scope 23 is a scope for observing the whole shots and is used to check the imprint state and the progress of mold pressing and filling of the imprint material 14. The optical path for the illumination system unit 2 and the shot whole area observation scope 23 can be switched by a half mirror 24.

### Imprint Method

Next, a description will be given of a mark detection method capable of stabilizing the time period from when the imprint material 14 is supplied onto the substrate 5 until when the mold pressing is performed by adjusting the illumination condition before supplying the imprint material 14 onto the substrate 5.

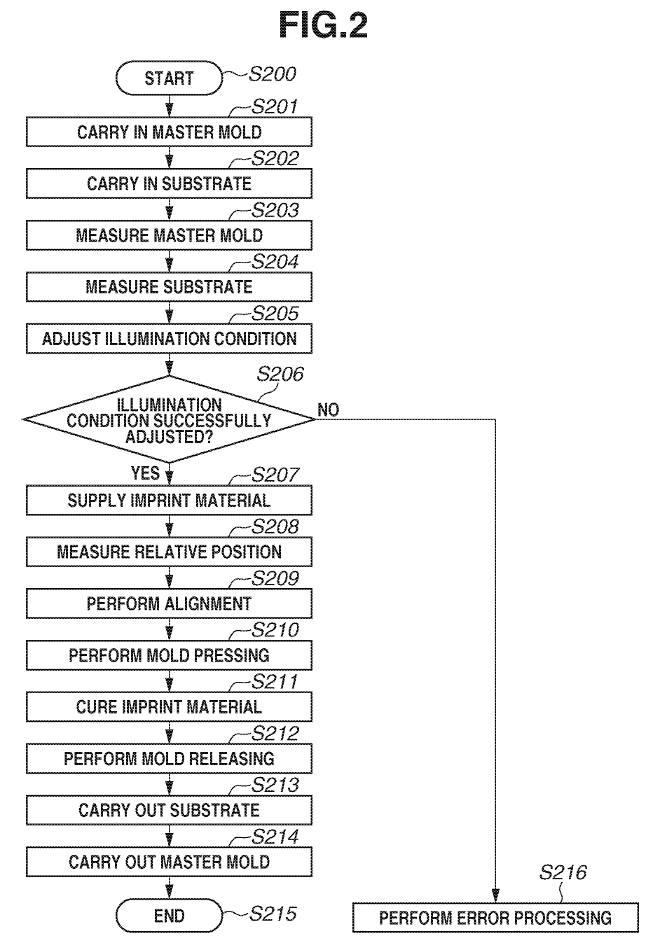

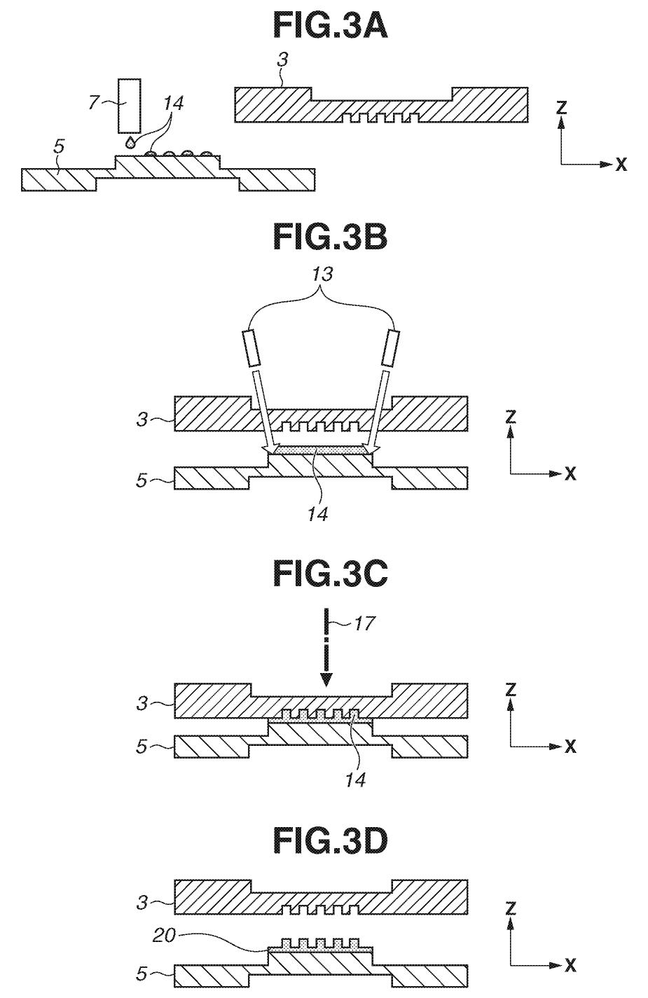

In addition, a description will be given of a method of manufacturing a replica mold by transferring a pattern formed on the master mold 3 to the substrate 5. FIG. 2 is a flowchart illustrating the replica mold manufacturing method (imprinting method) including a mark detection method according to the first embodiment. FIGS. 3A to 3D are diagrams illustrating a method (imprinting method) of forming a pattern of the imprint material 14 on the substrate 5 by the imprint processing.

In step S200 in FIG. 2, the imprint processing starts. In step S201, the mold conveyance apparatus 11 carries the master mold 3 into the imprint apparatus 1 to place the master mold 3 on the mold holding portion 4. Further, in step S202, the substrate conveyance apparatus 12 carries the substrate 5 into the imprint apparatus 1 to place the substrate 5 on the stage 6. The order of the processing in step S201 and the processing in step S202 may be swapped, or the processing in step S201 and the processing in S202 may be performed in parallel.

To detect the state of the master mold 3, the mold measurement sensor 9 then measures, in step S203, the inclination and the height of the surface of the master mold 3. To detect the state of the substrate 5, the substrate measurement sensor 8 also measures, in step S204, the inclination and the height of the surface of the substrate 5.

The inclination of the mold holding portion 4 is corrected such that the surfaces of the master mold 3 and the substrate 5 become parallel, based on the measurement results of the two sensors, e.g., the mold measurement sensor 9 and the substrate measurement sensor 8.

Next, in step S205, an illumination condition is adjusted so as to enable the mark detection of the master mold 3 and the substrate 5. As an example, the imprint apparatus 1 is mounted with the first to fourth TTM scopes 13. A description will be given of a case where four alignment marks are arranged each at a corner of the four corners of the pattern forming area of the master mold 3 and four alignment marks are arranged each at a corner of the four corners of the to-be-patterned area of the substrate 5, as the alignment marks to be detected by the TTM scopes 13.

First, the stage 6 is driven to place the alignment marks formed on the substrate 5 respectively under the corresponding alignment marks formed on the master mold 3. The stage 6 is driven based on the relative position of the to-be-patterned area of the substrate 5 with respect to the pattern forming area of the master mold 3.

Next, the first TTM scope 13 moves in the XY direction such that a first alignment mark of the master mold 3 and a first alignment mark of the substrate 5 are included within the image capturing range of the first TTM scope 13. The first TTM scope 13 is moved based on the design information about the arrangement of the first alignment mark formed on the master mold 3.

Next, the illumination conditions are adjusted. A first illumination condition under which both of the first alignment mark of the master mold 3 and the first alignment mark of the substrate 5 can be detected is obtained, by adjusting the wavelength and intensity of the light from the light source in the optical system of the first TTM scope 13 by using the adjustment unit. For example, the wavelength and intensity of the light are adjusted such that the amount of light from the first alignment mark of each of the master mold 3 and the first alignment mark of the substrate 5, and the contrast thereof satisfy a predetermined condition.

Similarly, the second to fourth illumination conditions are obtained under which second to fourth alignment marks formed on the master mold 3 and the second to fourth alignment marks formed on the substrate 5 can be detected, by using the second to fourth TTM scopes 13. The first to fourth illumination conditions are desirably obtained in parallel to shorten the processing time required for adjusting the illumination conditions, in a case where the movements of the first to fourth TTM scopes 13 in the XY direction do not interfere with each other. Upon completing the acquisitions of the first to fourth illumination conditions, the illumination condition adjustment is ended.

Next, in step S206, the control unit 10 determines whether the illumination conditions are successfully adjusted. In a case where any of the first to fourth illumination conditions cannot be adjusted (obtained) successfully (NO in step S206), the control unit 10 determines that the illumination condition cannot be adjusted, and the processing proceeds to step S216. In step S216, the control unit 10 performs error processing. In the error processing, the control unit 10 may stop the imprint processing without performing the processing of supplying the imprint material 14 in step S207, and the processing in the subsequent steps.

Examples of the adjustment failures of the illumination condition include a case where the illumination condition under which the alignment marks on both of the master mold 3 and the substrate 5 can be detected cannot be found, in a case where the difference of the reflectance ratios between the alignment mark formed on the master mold 3 and the alignment mark formed on the substrate 5 is large. In other words, it is a case where the illumination condition under which the mold mark and the substrate mark can be detected cannot be obtained. Further, the illumination condition adjustment fails also in a case where either of the alignment mark formed on the master mold 3 or the alignment mark formed on the substrate 5 is not present or both of them are not present within the image capturing ranges of the TTM scopes 13.

In a case where the illumination condition is successfully adjusted (YES in step S206), the processing proceeds to step S207. In step S207, the imprint material 14 is supplied onto the substrate 5. The imprint material 14 is supplied from the dispenser 7 to the to-be-patterned area (mesa portion, which is a protruding portion of the substrate 5) on the substrate 5, by driving the stage 6 to scan the substrate 5 below the dispenser 7 as illustrated in FIG. 3A.

Next, in step S208, the control unit 10 measures the relative position of the pattern forming area of the master mold 3 and the to-be-patterned area of the substrate 5, to obtain a misalignment amount of the relative position (first relative position) as illustrated in FIG. 3B. Details of the relative position measurement will be described below.

Next, in step S209, an alignment between the pattern forming area of the master mold 3 and the to-be-patterned area of the substrate 5 is performed. The relative position in the XY plane between the pattern forming area of the master mold 3 and the to-be-patterned area of the substrate 5 is corrected by driving the stage 6 in the XY direction and the XY rotation direction based on the misalignment amount of the relative position obtained in step S208.

Next, in step S210, the master mold 3 is brought into contact with and pressed against the imprint material 14 supplied on the substrate 5 as illustrated in FIG. 3C. The pattern of the imprint material 14 is formed in the to-be-patterned area (mesa portion) on the substrate 5 by the imprint material 14 entering the recessed portion formed in the master mold 3.

In step S211, the imprint material 14 is cured by emitting the light 17 from the illumination system unit 2 in a state where the master mold 3 is in contact with the imprint material 14.

After the imprint material 14 is cured, the master mold 3 is separated (released) from the cured imprint material 14, by increasing the distance between the master mold 3 and the substrate 5. As a result, in step S212, a pattern 20 of the cured imprint material 14 is formed on the substrate 5 as illustrated in FIG. 3D. An adhesion layer may also be provided on the surface of the substrate 5 so that the cured imprint material 14 is more likely to remain on the substrate 5.

Finally, in step S213, the substrate 5 on which the pattern 20 is formed is carried out of the imprint apparatus 1 by the substrate conveyance apparatus 12. In step S214, the master mold 3 is carried out of the imprint apparatus 1 by the mold conveyance apparatus 11. The order of the processing in step S213 and the processing in step S214 may be swapped, or the processing in step S213 and the processing in step S214 may also be performed in parallel. Then, in step S215, the series of imprint processing ends. In addition, in FIGS. 3A to 3D, the relationship between the master mold 3 and the substrate 5 is extracted from the imprint apparatus 1 and illustrated to simplify the drawings.

### Alignment Mark Measurement

The relative position measurement method performed in step S208 serving as the mark detection method according to the first embodiment will now be described.

Similar to the illumination condition adjustment performed in step S205, the first to fourth alignment marks of the substrate 5 are placed respectively under the first to fourth alignment marks of the master mold 3 by driving the stage 6.

Next, the first TTM scope 13 moves in the XY direction such that the first alignment mark formed on the master mold 3 and the first alignment mark formed on the substrate 5 are included within the image capturing range of the first TTM scope 13. In a case where the alignment marks on both of the master mold 3 and the substrate 5 have already been included within the image capturing range of the first TTM scope 13, the first TTM scope 13 does not need to be moved.

Next, the illumination system of the first TTM scope 13 is adjusted by the adjustment unit so as to be the first illumination condition acquired in step S205, and the image capturing range is captured by the image capturing system of the first TTM scope 13. Image recognition is performed using the acquired image information to detect the first alignment mark of the master mold 3 and the first alignment mark of the substrate 5. The misalignment amount of the first relative position on the XY plane between the first alignment marks on both of the master mold 3 and the substrate 5 can be obtained, from the positions of the first alignment marks on both of the master mold 3 and the substrate 5 in the image capturing range, and the image capturing magnification of the first TTM scope 13.

Similarly, the second to fourth alignment marks formed on the master mold 3 and the substrate 5 are adjusted to the illumination conditions obtained in step S205 to be detected by using the second to fourth TTM scopes 13, respectively. The misalignment amounts of the first to fourth relative positions are obtained based on the detection results of the second to fourth alignment marks, respectively.

Similar to the illumination condition adjustment in step S205, the first to fourth relative position measurements can be performed in parallel in the relative position measurement in step S208. Upon obtaining all the relative positions of the first to fourth alignment marks, the relative position measurements end.

In this way, the first to fourth alignment marks formed on the master mold 3 and the substrate 5 used in the first to fourth relative position measurements in step S208 are the same as the first to fourth alignment marks used for the adjustments of the illumination conditions in step S205.

As in the first embodiment, the misalignment amount in the XY direction as well as the misalignment amounts in the rotational direction can be measured by respectively obtaining the relative positions of the first to fourth alignment marks arranged at the four corners of the pattern forming area of the master mold 3 and the relative positions of the first to fourth alignment marks arranged at the four corners of the to-be-patterned area of the substrate 5.

### Mesa Edge Measurement

Up to now, the case where the alignment marks present on the master mold 3 and the substrate 5 are detected using the TTM scopes 13 has been described, but the detection targets are not necessarily the alignment marks, and the detection targets only need to be the targets detectable by image recognition. As an example of the relative position measurement using different detection targets as the alignment marks, a mark detection method (relative position measurement) using mesa edges will be described.

Usually, with a replica mold manufacturing apparatus serving as the imprint apparatus 1, a protruding portion called a mesa portion is formed on the substrate 5, and a pattern is formed inside the mesa portion by performing imprint processing. In a case where the alignment marks are not provided on the mesa portion of the substrate 5, four corners of the mesa portion may be the detection targets serving as the substrate marks in place of the alignment marks.

In this case, the illumination condition adjustments in step S205 and the relative position measurements in step S208 are performed by using the first to fourth alignment marks of the master mold 3 as the mold marks and using the first to fourth corners of the mesa portion of the substrate 5 as the substrate marks (detection targets).

Since the material with volatility is generally used as the imprint material 14, the imprint material supplied onto the substrate 5 is volatilized while the illumination condition is adjusted. Thus, when the time required for adjusting the illumination condition varies at each time of the mold pressing, the film thickness of the imprint material 14 on the substrate 5 may not have a desired film thickness. As described above, when the time required for adjusting the illumination condition varies at each time of the mold pressing, the time period from when the imprint material 14 is supplied onto the substrate until when the mold pressing is performed does not become constant.

According to the first embodiment, the illumination condition does not need to be adjusted when the relative position is measured using the marks after the imprint material 14 is supplied, by adjusting the illumination condition before the imprint material 14 is supplied onto the substrate 5. For this reason, it is possible to perform the mark detection under the appropriate illumination condition for each substrate, and reduce the time difference from when the imprint material 14 is supplied onto the substrate 5 until when the mold pressing is performed.

### SECOND EMBODIMENT

According to a second embodiment, a description will be given of a case where the illumination condition adjustment and the alignment mark detection are performed before supplying the imprint material onto the substrate. The description will be given of the mark detection method that can increase the alignment mark detection accuracy before the mold pressing, and stabilize the time period from when the imprint material is supplied onto the substrate until when the mold pressing is performed with this method.

### Imprint Method

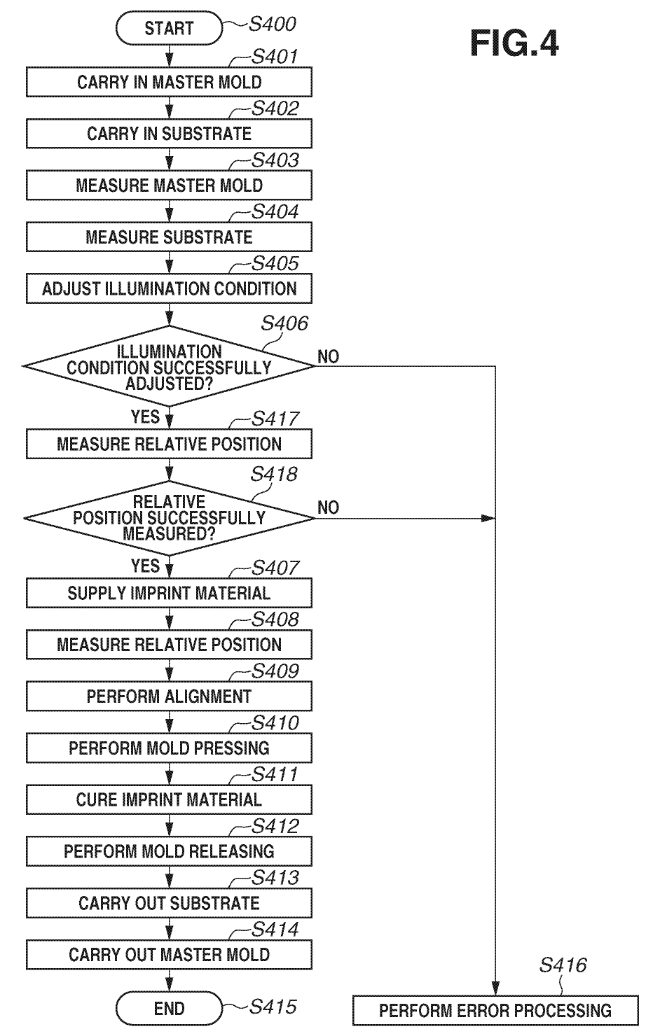

FIG. 4 is a flowchart illustrating a replica mold manufacturing method (imprinting method) according to the second embodiment.

In step S400, the imprint processing starts. Since processing to be performed in steps S400 to S406, and S416 is similar to that performed in steps S200 to S206, and S216 in FIG. 2 described according to the first embodiment, descriptions thereof will be omitted.

In a case where the illumination condition is successfully adjusted (YES in step S406), the processing proceeds to step S417. In step S417, the control unit 10 measures the relative position between the pattern forming area of the master mold 3 and the to-be-patterned area of the substrate 5. The control unit 10 measures the relative positions (second relative positions) between the first to fourth alignment marks of the master mold 3 and the first to fourth alignment marks of the substrate 5 to acquire the misalignment amounts of the first to fourth relative positions, respectively.

In the relative position measurements in step S417, the control unit 10 does not need to drive the stage 6 because the first to fourth alignment marks of the substrate 5 are respectively placed under the first to fourth alignment marks of the master mold 3 by the illumination condition adjustments in step S406. Further, the control unit 10 does not need to move the first to fourth TTM scopes 13 because the first to fourth alignment marks on both of the substrate 5 and the master mold 3 are respectively included within the corresponding image capturing ranges of the first to fourth TTM scopes 13.

Next, in step S418, the control unit 10 determines whether the relative position is successfully measured. In a case where the relative position is not successfully measured (NO in step S418), the processing proceeds to step S416. In step S416, the control unit 10 performs error processing. In the error processing, the control unit 10 stops the imprint processing without performing the processing of supplying the imprint material 14 in step S407, and the processing in the subsequent steps. In a case where the relative position is successfully measured (YES in step S418), the processing proceeds to step S407. In step S407, the imprint material 14 is supplied onto the substrate 5. Processing to be performed in step S407 is similar to that performed in step S207 in FIG. 2, and the description thereof is omitted.

Next, in step S408, the control unit 10 measures the relative position between the pattern forming area of the master mold 3 and the to-be-patterned area of the substrate 5. Similar to the illumination condition adjustment performed in step S405, the first to fourth alignment marks of the substrate 5 are respectively placed under the first to fourth alignment marks of the master mold 3 by moving the stage 6. At this time, the movement amount of the stage 6 is corrected based on the first to fourth relative position misalignment amounts between the alignment marks of the master mold 3 and the alignment marks of the substrate 5 acquired in step S417. For example, the relative position between the pattern forming area of the master mold 3 and the to-be-patterned area on the substrate 5 can be corrected, by correcting the movement amounts of the stage 6 in the XY direction and the XY rotation direction so that the sum total of the first to fourth relative position misalignment amounts becomes minimum.

The alignment marks on both of the master mold 3 and the substrate 5 can be captured near the centers of the image capturing ranges of the TTM scopes 13, by correcting the relative positions before the alignment in step S409 using the relative positions obtained in this way in step S417, respectively. Thus, it is possible to reduce the influence of aberrations of the image capturing system of each of the TTM scopes 13, and detect the alignment marks accurately.

Further, in the case where the relative position is not successfully measured in step S408, the control unit 10 may skip the processing of the alignment in step S409, and select to proceed to the mold pressing processing in step S410. For example, in a case where the relative position misalignment amount generated due to the driving of the stage 6 for supplying the imprint material 14 in step S407 is estimated to be within an allowable range set in advance, the alignment in step S409 may be omitted even if the relative position is not successfully measured in step S408. In this way, it is possible to continue the imprint processing without stopping the imprint processing while keeping the relative position misalignment amount within the allowable range.

The processing performed thereafter in step S408 is similar to that of the relative position measurement in step S208 according to the first embodiment, and the detailed description thereof will be omitted. Further, the alignment of the master mold 3 and the substrate 5 in step S409 is similar to that in step S209 according to the first embodiment, and the description thereof will be omitted. Further, processing in steps S409 to S416 is similar to that in steps S209 to S216, and the description thereof will be omitted.

According to the second embodiment, it is possible to perform the mark detection under the appropriate illumination condition for each substrate, increase the mark detection accuracy by the TTM scopes, and reduce the time difference from when the imprint material is supplied onto the substrate until when the mold pressing is performed.

### Imprint Apparatus according to Another Embodiment

In the embodiments described above, the imprint apparatus 1 serving as a pattern formation apparatus is described.

The above descriptions are given of the imprint apparatus 1 for manufacturing the replica mold using the master mold 3, but neither of the above-described embodiments is limited to the imprint apparatus 1 for manufacturing the replica mold.

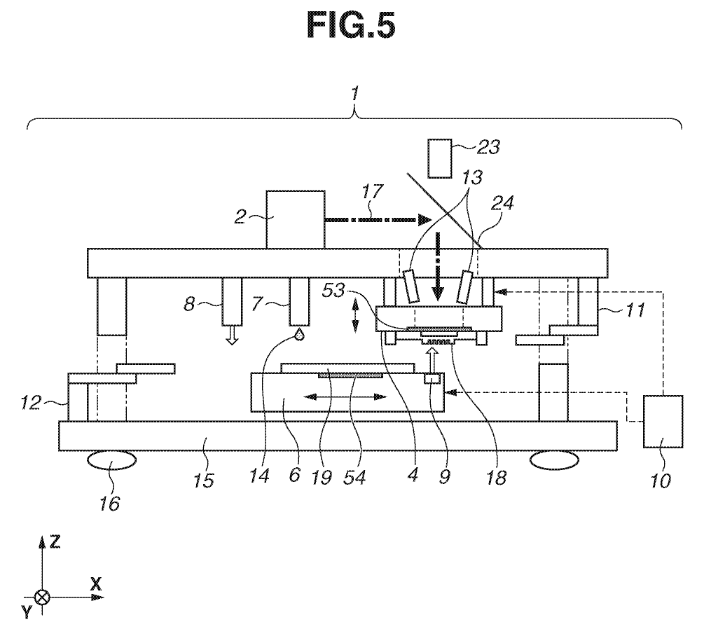

FIG. 5 is a diagram illustrating the imprint apparatus 1 for manufacturing semiconductor devices according to another embodiment. In the present embodiment, differences compared to the imprint apparatus 1 for manufacturing the replica mold illustrated in FIG. 1 will be described.

In the imprint apparatus 1 for manufacturing the semiconductor devices, a pattern is formed (transferred) on a wafer 19 serving as the substrate 5 instead of the blank mold serving as the substrate 5. Further, instead of the master mold 3, a mold 18 is mounted on the mold holding portion (imprint head) 4. Usually, a replica mold manufactured by the replica mold manufacturing apparatus in FIG. 1 is used for the mold 18.

The imprint processing is similar to that illustrated in FIG. 2 according to the first embodiment. By performing the imprint processing to each of the plurality of pattern forming areas formed on the wafer 19, circuit patterns required for manufacturing the semiconductor device can be formed on the entire surface of the wafer 19.

The mark detection method in the above-described embodiments can also be used for the semiconductor device manufacturing apparatus in FIG. 5. In the imprint apparatus 1 for manufacturing semiconductor devices, there is a case where the alignment between the pattern forming area of the mold 18 and the to-be-patterned area of the wafer 19 is performed in a state where the mold 18 is in contact with the wafer 19 at the mold pressing time in step S210, to increase the imprint accuracy. This is generally referred to as die-by-die alignment, and the alignment is performed by moving the stage 6 so as to correct the misalignment while observing the marks on both of the mold 18 and the wafer 19 with the TTM scopes 13.

Die-by-die alignment has a time constraint. Thus, the effect of increasing the imprint accuracy can be obtained by performing the alignment between the pattern forming area of the mold 18 and the to-be-patterned area of the wafer 19 described in the above-described embodiments before the die-by-die alignment is performed. Usually, in the semiconductor device manufacturing apparatus, a plurality of to-be-patterned areas (shot areas) is provided on the wafer 19. In this case, the mark detection method according to the above-described embodiments may be used for all the shot areas on the wafer 19, or may be used for only selected shot areas on the wafer 19.

### Article Manufacturing Method

The manufacturing method of devices (e.g., semiconductor integrated circuit (IC) elements and liquid crystal display elements) includes a process of forming patterns on a substrate (e.g., wafer, glass plate, and film-like substrate) using the above-described imprint apparatus 1. Further, the manufacturing method can include a process of etching the substrate with the patterns formed thereon. In addition, in a case where other articles such as patterned media (recording media) or optical elements are manufactured, the manufacturing method can include another process of processing the substrate with the patterns formed thereon, instead of the etching. The article manufacturing method according to the present embodiment is advantageous in at least one of the performance, quality, productivity, and production cost of the articles, compared with conventional methods.

According to the mark detection method disclosed in the embodiments, it is possible to perform the mark detection under the appropriate illumination condition for each substrate, and reduce the time difference from when the imprint material is supplied onto the substrate until when the mold pressing is performed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-054122, filed Mar. 27, 2025, which is hereby incorporated by reference herein in its entirety.

What is claimed is:

1. A mark detection method for detecting a substrate mark formed on a substrate and a mold mark formed on a mold when a pattern is formed using the mold on an imprint material supplied on the substrate, the mark detection method comprising:
adjusting, as an adjustment process, an illumination condition for mark detection by using the substrate mark and the mold mark;
supplying, as a supply process, the imprint material onto the substrate after the adjustment process;
measuring, as a first measurement process, a first relative position between the substrate mark and the mold mark by detecting the substrate mark and the mold mark based on the illumination condition after the supply process; and
aligning, as an alignment process, the substrate and the mold based on the first relative position,
wherein the substrate mark and the mold mark used in the adjustment process are identical to the substrate mark and the mold mark detected in the first measurement process.

2. The mark detection method according to claim 1, further comprising:
measuring, as a second measurement process, a second relative position between the substrate mark and the mold mark by detecting the substrate mark and the mold mark after the adjustment process and before the supply process; and
aligning a relative position between the substrate and the mold based on the second relative position when the first relative position is measured,
wherein the substrate mark and the mold mark detected in the first measurement process are identical to the substrate mark and the mold mark used in the second measurement process.

3. The mark detection method according to claim 2, wherein the second relative position between the substrate mark and the mold mark is not measured, in a case where the illumination condition under which the substrate mark and the mold mark can be detected is not obtained in the adjustment process.

4. The mark detection method according to claim 2, wherein the imprint material is not supplied onto the substrate, in a case where the second relative position between the substrate mark and the mold mark cannot be measured.

5. The mark detection method according to claim 2, wherein the substrate and the mold are aligned based on the second relative position, in a case where the first relative position cannot be measured in the first measurement process.

6. The mark detection method according to claim 1, wherein the imprint material is not supplied onto the substrate, in a case where the illumination condition under which the substrate mark and the mold mark can be detected is not obtained in the adjustment process.

7. A mark detection apparatus configured to detect a substrate mark formed on a substrate and a mold mark formed on a mold, in a case that a pattern is formed using the mold on an imprint material supplied onto the substrate, the mark detection apparatus comprising:
an adjustment unit configured to adjust an illumination condition for mark detection by using the substrate mark and the mold mark;
a supply unit configured to supply the imprint material onto the substrate after the illumination condition is adjusted by the adjustment unit;
a detection unit configured to detect the substrate mark and the mold mark illuminated based on the illumination condition, after the imprint material is supplied; and
a control unit configured to obtain a first relative position between the substrate mark and the mold mark detected by the detection unit, and control an alignment between the substrate and the mold based on the first relative position,
wherein the substrate mark and the mold mark used for adjusting the illumination condition are identical to the substrate mark and the mold mark detected when the first relative position is obtained.

8. A pattern formation apparatus configured to align the substrate and the mold, the apparatus comprising;
an illumination system configured to adjust an illumination condition for mark detection by using a substrate mark formed on the substrate and a mold mark formed on the mold;
a dispenser configured to supply the imprint material onto the substrate after the illumination condition is adjusted by the adjustment unit;
a scope configured to detect the substrate mark and the mold mark illuminated based on the illumination condition, after the imprint material is supplied; and
at least one processor or circuit configured to function as:
a control unit configured to obtain a first relative position between the substrate mark and the mold mark detected by the detection unit, and control an alignment between the substrate and the mold based on the first relative position,
wherein the substrate mark and the mold mark used for adjusting the illumination condition are identical to the substrate mark and the mold mark detected when the first relative position is obtained.

9. An article manufacturing method, comprising:
adjusting, as an adjustment process, an illumination condition for mark detection by using a substrate mark formed on a substrate and a mold mark formed on a mold;
supplying, as a supply process, an imprint material onto the substrate after the adjustment process;
measuring, as a first measurement process, a first relative position between the substrate mark and the mold mark by detecting the substrate mark and the mold mark based on the illumination condition after the supply process;
aligning, as an alignment process, the substrate and the mold based on the first relative position;
forming a pattern on the substrate, as a formation process; and
processing the substrate with the pattern formed thereon to manufacture an article,
wherein the substrate mark and the mold mark used in the adjustment process are identical to the substrate mark and the mold mark detected in the first measurement process.
